(19) United States
(12) Patent Application Publication
(10) Pub. No.: US 2009/0059984 A1
(43) Pub. Date: Mar. 5, 2009

(54) Nitride-based semiconductor light-emitting device

(75) Inventors: Masataka Ohta, Tenri-shi (JP); Yuhzoh Tsuda, Sakurai-shi (JP); Yukio Yamasaki, Osaka (JP)

Correspondence Address: HARNESS, DICKEY & PIERCE, P.L.C., P.O. BOX 8910, RESTON, VA, 20195, US

(73) Assignee: SHARP KABUSHIKI KAISHA

(21) Appl. No.: 12/230,364

(22) Filed: Aug. 28, 2008

(30) Foreign Application Priority Data
Aug. 30, 2007 (JP) 2007-224107 (P)

(51) Int. Cl. H01S 5/34

(52) U.S. Cl. 372/45.011

(57) ABSTRACT

A nitride-based semiconductor light-emitting device includes at least one n-type nitride-based semiconductor layer, an active layer having a quantum well structure, and at least one p-type nitride-based semiconductor layer successively stacked on a substrate, the active layer including an InGaN well layer and a barrier layer containing at least one of GaN and InGaN and having a light-emission wavelength in a range of 430 nm to 580 nm, the well layer having a thickness in a range of 1.2 nm to 4.0 nm, and the barrier layer being more than 10 times and at most 45 times as thick as the well layer.

This nonprovisional application is based on Japanese Patent Application No. 2007-224107 filed with the Japan Patent Office on Aug. 30, 2007, the entire contents of which are hereby incorporated by reference.

### FIELD OF THE INVENTION

The present invention relates to a nitride-based semiconductor light-emitting device, and particularly to improvement in light-emission characteristics of a nitride-based semiconductor light-emitting device having a light-emission wavelength in a range of 430 nm to 580 nm.

### DESCRIPTION OF THE BACKGROUND ART

In recent years, there have been many attempts to develop semiconductor light-emitting devices such as a semiconductor laser diode (LD) and a light-emitting diode (LED) capable of emitting light of blue or green by utilizing nitride-based semiconductor.

A light-emitting diode capable of emitting light of blue or green has already been put into practical use. In addition, in order to improve recording density of an optical recording medium such as an optical disk, a semiconductor laser device capable of emitting light of bluish violet in a region of wavelength around 400 nm has also been put into practical use.

On the other hand, there has been developed a semiconductor laser device capable of emitting light of pure blue or green in a region of wavelength longer than 400 nm, in expectation of application to a light source in a display device, a phosphor-stimulation light source for illumination, or medical equipment.

In a nitride-based semiconductor laser device having a light-emission wavelength in a range of 400 nm to 480 nm, an InGaN layer is mainly used as a well layer in an active layer (light-emitting layer) that has a quantum well structure including at least one quantum well layer and at least one barrier layer. In this case, the barrier layer can preferably be formed of a GaN layer or an InGaN layer that has a lower In concentration as compared to the well layer.

In order to achieve a light-emission wavelength longer than a wavelength of bluish violet light, it is necessary to increase the In composition ratio in group-III elements in the InGaN well layer, because the bandgap energy of the InGaN well layer decreases with increase of the In composition ratio and accordingly the light-emission wavelength becomes greater. With increase of the In composition ratio in the InGaN well layer, however, lattice strain of the active layer increases and crystallinity thereof is lowered. Consequently, the laser device's threshold current becomes higher, its light-emission efficiency is lowered, and then its reliability becomes poorer.

In order to proceed with development of nitride-based semiconductor laser devices for emitting light of pure blue or green having a wavelength longer than 400 nm, therefore, it is desirable to suppress deterioration in crystallinity of the well layer in the case that the In composition ratio in the InGaN well layer is increased involving increase of the lattice strain.

For example, Japanese Patent Laying-Open No. 2001-044570 discloses invention related to improvement in light-emission characteristics and lifetime of a nitride-based semiconductor laser device having a lasing wavelength not shorter than 420 nm. A nitride-based semiconductor laser device according to Japanese Patent Laying-Open No. 2001-044570 is characterized in that a barrier layer in an active layer having a quantum well structure has a thickness which is not smaller than 10 nm and in a range from three times to ten times the thickness of a well layer.

The active layer having the quantum well structure disclosed in Japanese Patent Laying-Open No. 2001-044570, however, does not seem sufficient as the active layer for the nitride-based semiconductor light-emitting device having a light-emission wavelength not shorter than 430 nm, which is further longer than 420 nm.

### SUMMARY OF THE INVENTION

In view of the foregoing, an object of the present invention is to further improve light-emission characteristics of a nitride-based semiconductor light-emitting device having a light-emission wavelength not shorter than 430 nm.

A nitride-based semiconductor light-emitting device according to the present invention includes: at least one n-type nitride-based semiconductor layer; an active layer having a quantum well structure; and at least one p-type nitride-based semiconductor layer, successively stacked on a substrate. The active layer includes at least one quantum well layer of InGaN and at least one barrier layer of GaN or InGaN and has a light-emission wavelength in a range of 430 nm to 580 nm. The well layer has a thickness in a range of 1.2 nm to 4.0 nm. The barrier layer has a thickness more than 10 times and not more than 45 times the thickness of the well layer.

Here, an average strain εₐᵥₑ of a light-emitting layer can be expressed in the following Equation (1) disclosed by M. Ogasawara, H. Sugiura, M. Mitsuhara, M. Yamamoto, and M. Nakao, “Influence of net strain, strain-type, and temperature on the critical thickness of In(Ga)AsP-strained multi quantum wells,” Journal of Applied Physics, volume 84, number 9, (1998), p. 4775. In Equation (1), ε_{W} represents a strain of a quantum well layer, L_{w} represents a thickness of the quantum well layer, ε_{b} represents a strain of a barrier layer, and ε_{b} represents a thickness of the barrier layer.

$${ɛ}_{ave} = \frac{{ɛ}_{W} \cdot {L}_{W} + {ɛ}_{b} \cdot {L}_{b}}{{L}_{W} + {L}_{b}} \times 100 ( \% ) \qquad ( 1 )$$

As can be seen from Equation (1), by setting thickness L_{W} of the well layer to a small value in a range of 1.2 nm to 4.0 nm, it is possible to make smaller a product of strain ε_{W} and L_{W} regarding the well layer (i.e., the numeric value of the first term in the numerator can be made smaller) and then average strain εₐᵥₑ of the light-emitting layer can be made smaller. In addition, by making thickness L_{b} of the barrier layer greater in a state of thickness L_{W} of the well layer being small, average strain εₐᵥₑ of the light-emitting layer can be made smaller. The barrier layer desirably has a thickness more than 10 times and not more than 45 times the thickness of the well layer, in consideration of an optical confinement effect in the active layer (see FIG. 4) and a carrier injection property.

Here, the nitride-based semiconductor light-emitting device may be a nitride-based semiconductor laser device. The number of quantum well layers is preferably in a range from two to six. In the case of the number of well layers being two or more, the effect of the suppression of average strain achieved by the barrier layer is improved as compared to the case of a single well layer (see FIG. 5). In the case of the number of well layers being seven or more, on the other hand, it is expected that deterioration in the light-emission characteristics is caused by non-uniform carrier injection.

Preferably, the barrier layer has a thickness more than 12 nm and less than 100 nm on the condition that it is more than 10 times as thick as the well layer. If the barrier layer has a thickness not greater than 12 nm, the buffering function becomes insufficient. If the barrier layer has a thickness not smaller than 100 nm, on the other hand, there is a possibility that the carrier injection becomes non-uniform, and there is also a possibility that the coefficient of optical confinement in the active layer is lowered thereby causing deterioration of the light-emission efficiency.

Preferably, the In composition ratio in group-III elements in the well layer is in a range of 0.05 to 0.50. In addition, the In composition ratio in group-III elements in the barrier layer is preferably in a range of 0.00 to 0.20. With such ranges of the In composition ratio, the light-emission wavelength can be in a range of 430 nm to 580 nm.

The barrier layer may include a plurality of layers having different In composition ratios, and the In composition ratios of these layers are smaller than the In composition ratio of the well layer. For example, as compared with a barrier layer including a single GaN layer, a barrier layer having a multilayer structure in which a GaN layer is sandwiched between two InGaN layers can improve the optical confinement efficiency in the light-emitting layer and is also preferred from a point of view of more effective strain relaxation.

Preferably, at least one n-type nitride-based semiconductor layer includes an n-type clad layer, at least one p-type nitride-based semiconductor layer includes a p-type clad layer, and the Al composition ratio in group-III elements in these clad layers is in a range of 0.01 to 0.15. If the Al composition ratio in the clad layer is smaller than 0.01, the difference in refraction index with respect to the active layer tends to be smaller, the optical confinement function tends to lower, and the operating current of the light-emitting device tends to increase. In contrast, if the Al composition ratio is greater than 0.15, it becomes difficult to obtain a crystal of low electric resistance, an operating voltage of the light-emitting device tends to increase, and dislocations may be generated.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view showing an example of a nitride-based semiconductor light-emitting device according to the present invention.

FIG. 2 is a schematic cross-sectional view showing an example of a quantum well structure of an active layer included in the nitride-based semiconductor light-emitting device according to the present invention.

FIG. 3 is a schematic cross-sectional view showing another example of a quantum well structure of an active layer included in the nitride-based semiconductor light-emitting device according to the present invention.

FIG. 4 is a graph showing the relation between the ratio of thickness of the barrier layer to that of the quantum well layer and the normalized optical confinement coefficient in the active layer.

FIG. 5 is a graph showing the relation between the ratio of thickness of the barrier layer to that of the quantum well layer and the average strain of the active layer.

FIGS. 6 and 7 are schematic cross-sectional views showing yet other examples of the quantum well structure of the active layer included in the nitride-based semiconductor light-emitting device according to the present invention.

### DESCRIPTION OF THE PREFERRED EMBODIMENTS

The present inventors have conceived that the deterioration of light-emission efficiency in the case of increasing the In composition ratio in the InGaN well layer in the light-emitting layer having the quantum well structure may result from possible increase in crystal defect density due to increase in lattice strain. Specifically, since a crystal defect can be a nonradiative center, increase in crystal defect density results in deterioration in light-emission efficiency. In the light-emitting layer having the quantum well structure according to the present invention, it is intended to suppress increase in crystal defect density in the case of increasing the In composition ratio in the InGaN well layer.

### First Embodiment

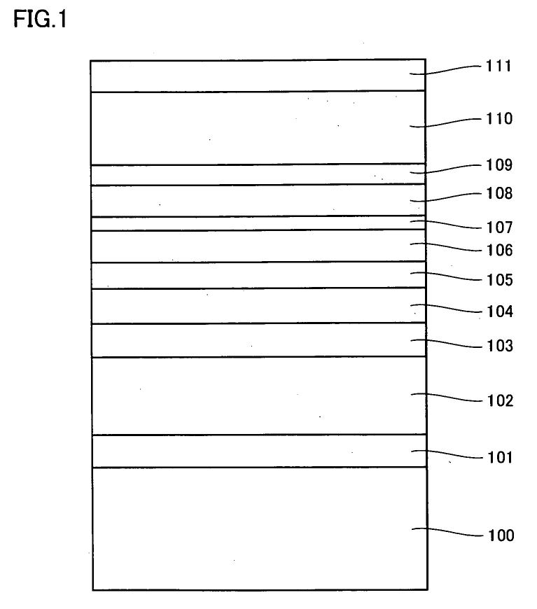

The schematic cross-sectional view of FIG. 1 shows a stacked-layer structure of a nitride-based semiconductor light-emitting device according to the first embodiment of the present invention. In the drawings of the present application, dimensions such as length, width, and thickness are arbitrarily modified for clarity and simplification of the drawings, so that actual dimensional relations are not shown. In particular, the thickness is shown with arbitrary enlargement. In the drawings, the same reference numbers represent the same or corresponding portions.

The nitride-based semiconductor light-emitting device of FIG. 1 includes an n-type GaN layer 101 (thickness 0.5 cm), an n-type AlₓGa₁₋ₓN (0.01≦x≦0.15) lower clad layer 102, an n-type GaN lower guide layer 103 (thickness 0.1 μm), an undoped GaN or InGaN lower adjacent layer 104, an active layer 105, an undoped GaN or InGaN upper adjacent layer 106, an n-type GaN guide layer 107 (thickness 110 nm) serving as a first layer, an undoped GaN layer 108 (thickness 40 nm) serving as a second layer, a p-type Al_{0.30}Ga_{0.70}N layer 109 (thickness 20 nm) serving as a third layer, a p-type AlₓGa₁₋ₓN (0.01≦x≦0.15) upper clad layer 110, and an Mg-doped p-type GaN contact layer 111 (thickness 0.1 μm), successively stacked on an n-type GaN substrate 100.

It is noted that n-type AlₓGa₁₋ₓN (0.01≦x≦0.15) lower clad layer 102 or p-type AlₓGa₁₋ₓN (0.01≦x≦0.15) upper clad layer 110 may have a superlattice structure. Here, if Al composition ratio x in the clad layer is smaller than 0.01, the refraction index of the clad layer increases thereby making smaller the difference in refraction index in comparison with the active layer, which causes lowering in the optical confinement function derived from the difference in refraction index and hence results in greater operating current of the light-emitting device. In contrast, if Al composition ratio x in the clad layer is greater than 0.15, the electrical resistance of the clad layer increases and thus the operating voltage of the light-emitting device becomes higher.

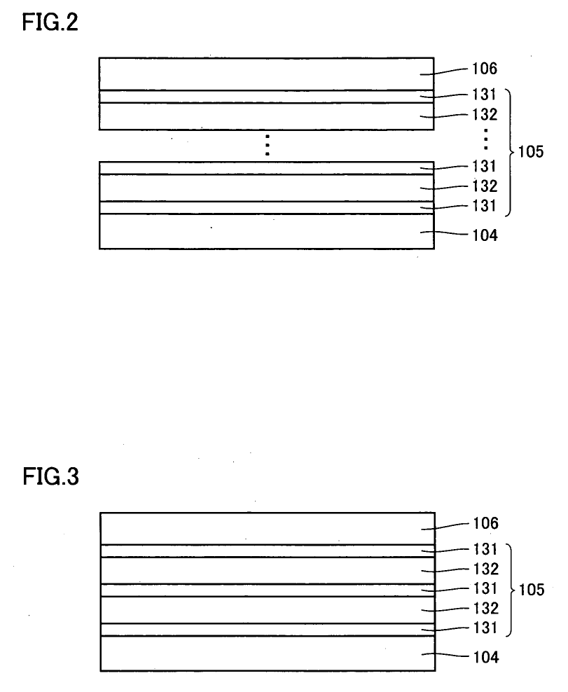

The schematic cross-sectional view of FIG. 2 shows in further detail the quantum well structure of active layer 105. In active layer 105, an undoped InGaN well layer 131 has a small thickness in a range of 1.2 nm to 4.0 nm, the In composition ratio in group-III elements is in a range of 0.05 to 0.50, and the light-emission wavelength is in a range of 430 nm to 580 nm. On the other hand, an undoped barrier layer 132 contains at least one of GaN and InGaN. In addition, barrier layer 132 has a thickness in a range from more than 10 times to not more than 45 times the thickness of the well layer so that it can serve as a buffer layer reducing the average strain of the well layer.

In the quantum well structure in FIG. 2, well layer 131 and barrier layer 132 are alternately stacked, and the stacking starts with the well layer and ends with the well layer. Active layer 105 may have a multiple quantum well structure including two to six well layers, and the lowermost well layer abuts on lower adjacent layer 104 and upper adjacent layer 106 is provided on the uppermost well layer. So long as the light-emission wavelength is adjusted to be in a range of 430 nm to 580 nm and the bandgap energy of the barrier layer is adjusted to be greater than that of the well layer, the well layer or the barrier layer is not limited to a layer formed of a compound semiconductor described above, and it may be formed of InAlGaN or any of the other nitride-based semiconductors.

A layer adjacent to lowermost or uppermost well layer 131 (lower adjacent layer 104, upper adjacent layer 106) is formed of GaN or InGaN and should be undoped as described above. This is because carriers may quantally seep from the active layer into the vertically adjacent layer, and if the vertically adjacent layer contains a conductivity-type impurity, the seeping carriers are trapped in that layer, which results in lowering in carrier injection efficiency.

As described above, a GaN substrate is most preferably used as substrate 100 from a point of view of suppressing lattice mismatch with nitride-based semiconductor layers 101 to 111 stacked thereon. Instead, however, it is also possible to use an AlGaN substrate. As the main surface of the GaN substrate or the AlGaN substrate, it is possible to use a (0001) plane, a (10-10) plane, a (11-20) plane, a (11-22) plane, or the like. It is noted that each of the (10-10) plane and the (11-20) plane are a non-polar plane of a nitride-based semiconductor.

A light-emitting device having such a nitride-based semiconductor stacked-layer structure as shown in FIG. 1 can be fabricated by forming the stacked-layer structure with a known crystal growth method such as metal-organic chemical vapor deposition (MOCVD) and further depositing an electrode (not shown) with evaporation.

### Example 1

Example 1 according to the present invention corresponds to the first embodiment described above. A semiconductor light-emitting device of Example 1 is a semiconductor laser device having a light-emission wavelength of 445 nm, and reference to FIG. 1 can be made again in regard to the stacked-layer structure of this device.

Referring to FIG. 1, the nitride-based semiconductor laser device of Example 1 includes an Si-doped n-type GaN layer 101 (thickness 0.5 μm), an Si-doped n-type Al_{0.06}Ga_{0.94}N lower clad layer 102 (thickness 2.2 μm), an Si-doped n-type GaN lower guide layer 103 (thickness 0.1 μm), an undoped In_{0.02}Ga_{0.98}N lower adjacent layer 104 (thickness 20 nm), active layer 105, an undoped In_{0.02}Ga_{0.98}N upper adjacent layer 106 (thickness 20 nm), n-type GaN guide layer 107 (thickness 10 nm) serving as the first layer, undoped GaN layer 108 (thickness 40 nm) serving as the second layer, an Mg-doped p-type Al_{0.30}Ga_{0.70}N layer 109 (thickness 20 nm) serving as the third layer, an Mg-doped p-type Al_{0.06}Ga_{0.94}N upper clad layer 110 (thickness 0.55 μm), and Mg-doped p-type GaN contact layer 111 (thickness 0.1 μm), successively stacked on n-type GaN substrate 100.

The layer adjacent to lowermost or uppermost well layer 131 (lower adjacent layer 104, upper adjacent layer 106) is undoped as described previously.

The schematic cross-sectional view of FIG. 3 shows in further detail active layer 105 and the layers adjacent thereto in present Example 1. Active layer 105 has a multiple quantum well structure obtained by alternately stacking an undoped In_{0.15}Ga_{0.85}N well layer 131 and an undoped GaN barrier layer 132 starting with the well layer and ending with the well layer, and includes three well layers. In_{0.15}Ga_{0.85}N well layer 131 has a thickness of 2.5 nm, and GaN barrier layer 132 has a thickness of 32 nm. Namely, the barrier layer was 12.8 times as thick as the well layer. By setting the well layer to a thickness as small as 2.5 nm and setting the barrier layer more than 10 times as thick as the well layer, it was possible to confirm suppression of generation of crystal defects in the light-emitting layer.

The semiconductor laser device of Example 1 was subjected to measurement of electroluminescence, and as a result it was confirmed that light-emission intensity thereof was several times higher than that of a device in which In_{0.15}Ga_{0.85}N well layer 131 was set to a thickness of 2.5 nm and GaN barrier layer 132 was at least 1 time and at most 10 times as thick as the well layer. Namely, the semiconductor laser device of Example 1 can achieve its lasing property of high light-emission efficiency and also achieve reduction in threshold current, improvement in temperature characteristics and improvement in lifetime property.

### Example 2

Example 2 according to the present invention also corresponds to the first embodiment described above, similarly to Example 1. In this Example 2, the optical confinement coefficient was calculated with the thickness of In_{0.15}Ga_{0.85}N well layer 131 being set to 2.5 nm and the thickness of GaN barrier layer 132 serving as a parameter in regard to active layer 105 in the laser device structure of Example 1. The calculation method is disclosed in M. J. Bergmann and H. C. Casey, Jr., “Optical-field calculations for lossy multiple-layer AlₓGa₁₋ₓN/InₓGa₁₋ₓN laser diodes,” Journal of Applied Physics, volume 84, number 3, (1998), p. 1196.

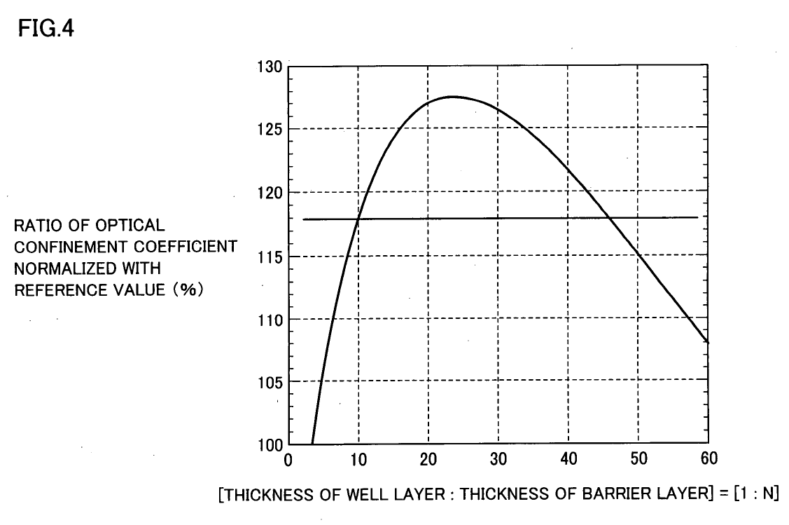

The graph of FIG. 4 shows the relation between the ratio of thickness of the barrier layer to that of the well layer and the normalized optical confinement coefficient. As can be seen from FIG. 4, when the thickness of the barrier layer is increased exceeding 10 times that of the well layer, the optical confinement coefficient can increase by approximately up to 10% as compared with an example in which the barrier layer is 10 times as thick as the well layer, whereby it becomes possible to realize a laser device that can achieve high light-emission efficiency and also achieve reduction in threshold current, improvement in temperature characteristics and improvement in lifetime property. On the other hand, if the thickness of the barrier layer is increased exceeding 45 times that of the well layer, the optical confinement coefficient decreases as compared with the example in which the barrier layer is 10 times as thick as the well layer. Namely, the barrier layer preferably has a large thickness from a point of view of serving as a strain-buffering layer, while it is desirably at most 45 times as thick as the well layer from a point of view of the optical confinement coefficient.

### Example 3

Example 3 according to the present invention also corresponds to the first embodiment described above, similarly to Example 1. In this Example 3, the average strain of the active layer was calculated with the thickness of In_{0.15}Ga_{0.85}N well layer 131 being set to 2.5 nm and the thickness of GaN barrier layer 132 serving as a parameter in regard to active layer 105 in the laser device structure of Example 1. The average strain of the active layer can be given based on Equation (1) described previously.

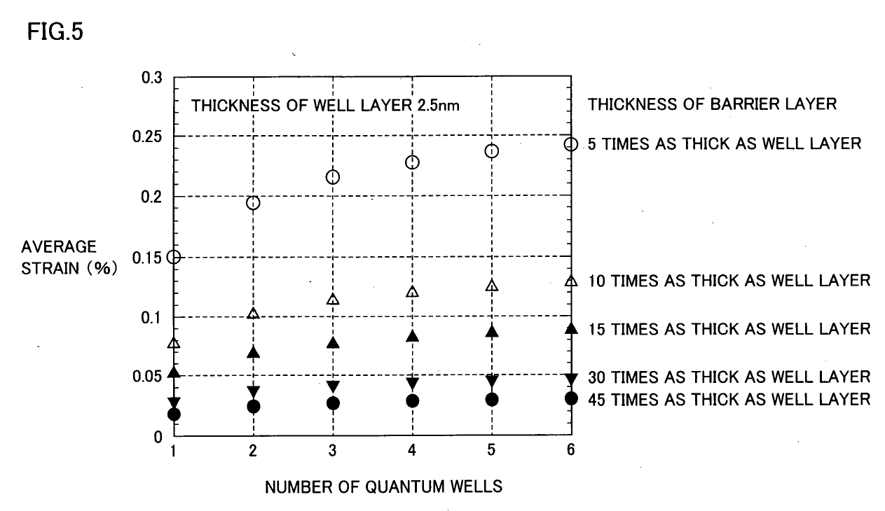

The graph of FIG. 5 shows a result of calculation based on the following Equation (2) obtained by developing Equation (1) in consideration of the number of well layers and the number of barrier layers. Specifically, Equation (1) represents an example in which the number of well layers is set to 1 and the number of barrier layers is set to 1, while N_{qw} in Equation (2) represents the number of well layers.

$${ɛ}_{ave} = \frac{{ɛ}_{W} \cdot ( {N}_{qw} \cdot {L}_{W} ) + {ɛ}_{b} \cdot ( ( {N}_{qw} + 1 ) \cdot {L}_{b} )}{( {N}_{qw} \cdot {L}_{W} ) + ( ( {N}_{qw} + 1 ) \cdot {L}_{b} )} \times 100 ( \% ) \qquad ( 2 )$$

This Equation (2) represents an application to the multiple quantum well structure that includes N_{qw} well layers and N_{qw}+1 barrier layers. Specifically, the multiple quantum well structure to which Equation (2) is applied has a stacked-layer structure including a barrier layer/a well layer/a barrier layer/ . . . /a well layer/a barrier layer, starting with the barrier layer and ending with the barrier layer. Therefore, number N_{qw}+1 of barrier layers is greater by 1 than number N_{qw} of well layer(s). In Equation (2), when the number of well layers is 1, the well layer has a thickness of L_{W}, whereas when the number of well layers is N_{qw}, the total thickness of the well layers is calculated as N_{qw}L_{W} that is obtained by multiplying number N_{qw} of well layers by thickness L_{W}. The same relation is also applicable to the barrier layers.

In Example 3, the average strain of the active layer was calculated with the number of quantum well layers being set to a value in a range from two to six. In FIG. 5, a white circle, a white triangle, a black triangle, a black inverted triangle, and a black circle indicate results of calculation in the case that the barrier layer is 5 times, 10 times, 15 times, 30 times, and 45 times as thick as the well layer, respectively.

According to FIG. 5, when the thickness of the barrier layer is increased exceeding 10 times that of the well layer, the reduction ratio of average strain in the active layer is greater in the case of including two or more well layers as compared to in the case of including a single well layer. In the case of including seven or more quantum well layers, on the other hand, it is expected that the light-emission characteristics deteriorate due to non-uniform carrier injection into the active layer.

As can be seen from FIG. 5, by setting the barrier layer more than 10 times as thick as the well layer, influence of strain of the well layers can sufficiently be suppressed even though the number of quantum well layers is increased to six. Namely, according to Example 3, when the number of well layers is in a range from two to six, it can be seen that it is possible to realize a laser device that can achieve high light-emission efficiency and also achieve reduction in threshold current, improvement in temperature characteristics and improvement in lifetime property.

As shown in FIG. 5, the average strain of the active layer monotonously decreases in the case of increasing the ratio of thickness of the barrier layer to that of the well layer. Namely, from a point of view of the average strain of the active layer, there is no necessary upper limit of the ratio of thickness of the barrier layer to that of the well layer, whereas from a point of view of the optical confinement coefficient shown in previous FIG. 4, the ratio of thickness of the barrier layer to that of the well layer is desirably at most 45 times.

### Example 4

Example 4 according to the present invention also corresponds to the first embodiment described above, similarly to Example 1. A laser device structure according to Example 4 was different from that of Example 1 in that the GaN barrier layer was replaced with an In_{0.03}Ga_{0.97}N barrier layer.

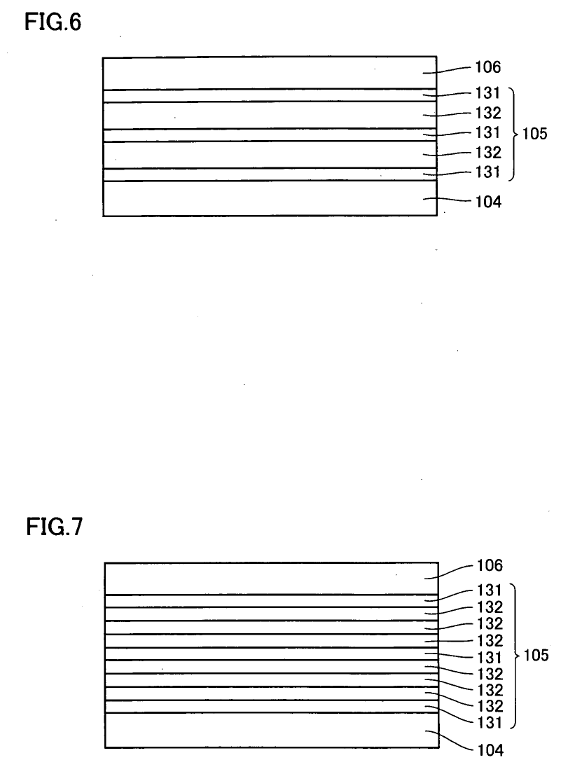

The schematic cross-sectional view of FIG. 6 shows in further detail active layer 105 and the layers adjacent thereto in Example 4. Active layer 105 has a multiple quantum well structure including undoped In_{0.15}Ga_{0.85}N well layer 131 and undoped In_{0.03}Ga_{0.97}N barrier layer 132 starting with the well layer and ending with the well layer, and includes three well layers. In_{0.15}Ga_{0.85}N well layer 131 has a thickness of 2.5 nm, and In_{0.03}Ga_{0.97}N barrier layer 132 has a thickness of 32 nm. Namely, the barrier layer was 12.8 times as thick as the well layer. By setting the well layer to a thickness as small as 2.5 nm and setting the barrier layer more than 10 times as thick as the well layer, it was possible to confirm suppression of generation of crystal defects in the light-emitting layer.

The semiconductor laser device of Example 4 was subjected to electroluminescence measurement, and as a result it was confirmed that its light-emission intensity thereof was several times higher than that of a device in which In_{0.15}Ga_{0.85}N well layer 131 was set to a thickness of 2.5 nm and In_{0.03}Ga_{0.97}N barrier layer 132 was at least 1 time and at most 10 times as thick as the well layer. Namely, the semiconductor laser of Example 4 can achieve its lasing property of high light-emission efficiency and also achieve reduction in threshold current, improvement in temperature characteristics and improvement in lifetime property.

### Example 5

Example 5 according to the present invention also corresponds to the first embodiment described above, similarly to Example 4. In Example 5, the optical confinement coefficient was calculated with the thickness of In_{0.15}Ga_{0.85}N well layer 131 being set to 2.5 nm and the thickness of In_{0.03}Ga_{0.97}N barrier layer 132 serving as a parameter in regard to active layer 105 in the laser device structure of Example 4.

The result of calculation in Example 5 is similar to that shown in the graph of FIG. 4, and the optical confinement coefficient can be increased by setting the barrier layer more than 10 times as thick as the well layer. Here, since the refraction index of the In_{0.03}Ga_{0.97}N barrier layer in Example 4 is higher than that of the GaN barrier layer in Example 1, the refraction index of active layer 105 in Example 4 becomes higher and hence the optical confinement effect becomes higher as compared with the example using the GaN barrier layer. In addition to this effect, by setting the barrier layer more than 10 times as thick as the well layer, the optical confinement coefficient can be increased by approximately up to 10%. Consequently, in Example 4, it becomes possible to realize a laser device that can achieve further higher light-emission efficiency and also achieve reduction in threshold current, improvement in temperature characteristics and improvement in lifetime property.

### Second Embodiment

As compared to the first embodiment, a nitride-based semiconductor light-emitting device according to the second embodiment of the present invention is different only in that the active layer is modified.

In active layer 105 according to the second embodiment as well, undoped InGaN well layer 131 has a small thickness in a range of 1.2 nm to 4.0 nm, the In composition ratio in group-III elements is in a range of 0.05 to 0.50, and the light-emission wavelength is in a range of 430 nm to 580 nm. In addition, barrier layer 132 is more than 10 times and at most 45 times as thick as the well layer so that it can serve as a buffer layer relaxing strain of the well layer.

Barrier layer 132 according to the present second embodiment has a stacked-layer structure including a plurality of InGaN layers having In composition ratios different from each other, and these In composition ratios in group-III elements are in a range of 0.00 to 0.20.

### Example 6

Example 6 of the present invention corresponds to the second embodiment described above. The semiconductor light-emitting device of Example 6 is also a semiconductor laser device having a light-emission wavelength of 445 nm, and reference to FIG. 1 can be made again in regard to the stacked-layer structure of this device.

Referring to FIG. 1, the nitride-based semiconductor laser device of Example 6 includes Si-doped n-type GaN layer 101 (thickness 0.5 μm), Si-doped n-type Al_{0.06}Ga_{0.94}N lower clad layer 102 (thickness 2.2 μm), Si-doped n-type GaN lower guide layer 103 (thickness 0.1 μm), undoped In_{0.02}Ga_{0.98}N lower adjacent layer 104 (thickness 20 nm), active layer 105, undoped In_{0.02}Ga_{0.98}N upper adjacent layer 106 (thickness 20 nm), n-doped GaN guide layer 107 (thickness 10 nm) serving as the first layer, undoped GaN layer 108 (thickness 40 nm) serving as the second layer, Mg-doped p-type Al_{0.30}Ga_{0.70}N layer 109 (thickness 20 nm) serving as the third layer, Mg-doped p-type Al_{0.06}Ga_{0.94}N upper clad layer 110 (thickness 0.55 μm), and Mg-doped p-type GaN contact layer 111 (thickness 0.1 μm), successively stacked on n-type GaN substrate 100.

The layer adjacent to lowermost or uppermost well layer 131 (lower adjacent layer 104, upper adjacent layer 106) is undoped as described above.

The schematic cross-sectional view of FIG. 7 shows in further detail the quantum well structure of active layer 105 in Example 6. Active layer 105 has the quantum well structure obtained by alternately stacking undoped In_{0.15}Ga_{0.85}N well layer 131 and undoped barrier layer 132 starting with the well layer and ending with the well layer, and includes three well layers. Barrier layer 132 has a three-layered structure of In_{0.03}Ga_{0.97}N/GaN/In_{0.03}Ga_{0.97}N.

The thickness of In_{0.15}Ga_{0.85}N well layer 131 was set to 2.5 nm. On the other hand, the thicknesses of In_{0.03}Ga_{0.97}N/GaN/In_{0.03}Ga_{0.97}N included in barrier layer 132 were set to 12 nm/8 nm/12 nm, respectively, so that the total thickness was set to 32 nm. Namely, the total thickness of the barrier layer was 12.8 times as thick as the well layer. By setting the well layer to a thickness as small as 2.5 nm and setting the barrier layer more than 10 times as thick as the well layer, it was possible to confirm suppression of generation of crystal defects in the light-emitting layer.

The semiconductor laser device of Example 6 was subjected to measurement of electroluminescence, and as a result it was confirmed that light-emission intensity thereof was several times higher than that of a device in which In_{0.15}Ga_{0.85}N well layer 131 was set to a thickness of 2.5 nm and the GaN barrier layer was at least 1 time and at most 10 times as thick as the well layer. Namely, the semiconductor laser device of Example 6 can also achieve high light-emission efficiency, and also achieve reduction in threshold current, improvement in temperature characteristics, and improvement in lifetime property.

### Example 7

Example 7 according to the present invention also corresponds to the second embodiment described above, similarly to Example 6. With regard to active layer 105 in the laser device structure of Example 7, the optical confinement coefficient was calculated with the thickness of In_{0.15}Ga_{0.85}N well layer 131 being set to 2.5 nm and the total thickness of barrier layer 132 composed of three layers of In_{0.03}Ga_{0.97}N/GaN/In_{0.03}Ga_{0.97}N serving as a parameter. The result of calculation exhibits a tendency similar to FIG. 4. Specifically, by setting the barrier layer more than 10 times as thick as the well layer, the optical confinement coefficient can be increased by approximately up to 10% as compared with the example in which the barrier layer is 10 times as thick as the well layer, and it becomes possible to realize a laser device that can achieve higher light-emission efficiency and also achieve reduction in threshold current, improvement in temperature characteristics and improvement in lifetime property.

As described above, according to the present invention, the nitride-based semiconductor light-emitting device having a light-emission wavelength not shorter than 430 nm can achieve reduction in crystal defects caused by lattice strain in the light-emitting layer and then achieve improved light-emission efficiency. Furthermore, in the case that the light-emitting device is the laser device, the optical confinement coefficient can be increased, which also contributes to improvement in light-emission efficiency.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A nitride-based semiconductor light-emitting device, comprising:
at least one n-type nitride-based semiconductor layer, an active layer having a quantum well structure and at least one p-type nitride-based semiconductor layer successively stacked on a substrate,
said active layer including an InGaN quantum well layer and a barrier layer containing at least one of GaN and InGaN and having a light-emission wavelength in a range of 430 nm to 580 nm,
said well layer having a thickness in a range of 1.2 nm to 4.0 nm, and
said barrier layer being more than 10 times and at most 45 times as thick as said well layer.

2. The nitride-based semiconductor light-emitting device according to claim 1, wherein
said nitride-based semiconductor light-emitting device is a nitride-based semiconductor laser device.

3. The nitride-based semiconductor light-emitting device according to claim 1, wherein
said active layer includes at least two and at most six well layers.

4. The nitride-based semiconductor light-emitting device according to claim 1, wherein
said barrier layer has a thickness greater than 0.12 nm and smaller than 100 nm.

5. The nitride-based semiconductor light-emitting device according to claim 1, wherein
an In composition ratio in group-III elements in said well layer is in a range of 0.05 to 0.50.

6. The nitride-based semiconductor light-emitting device according to claim 1, wherein
an In composition ratio in group-III elements in said barrier layer is in a range of 0.00 to 0.20.

7. The nitride-based semiconductor light-emitting device according to claim 1, wherein
said barrier layer includes a plurality of layers having In composition ratios different from each other, and the In composition ratios in the plurality of layers are smaller than a In composition ratio in said well layer.

8. The nitride-based semiconductor light-emitting device according to claim 7, wherein
said barrier layer includes an InGaN layer and a GaN layer.

9. The nitride-based semiconductor light-emitting device according to claim 1, wherein
said at least one n-type nitride-based semiconductor layer includes an n-type clad layer, said at least one p-type nitride-based semiconductor layer includes a p-type clad layer, and an Al composition ratio in group-III elements in these clad layers is in a range of 0.01 to 0.15.
